(19) United States
(12) Patent Application Publication
(10) Pub. No.: US 2026/0190390 A1
(43) Pub. Date: Jul. 2, 2026

(54) THIN FILM TRANSISTOR AND DISPLAY APPARATUS COMPRISING THE SAME

(71) Applicant: LG Display Co., Ltd., Seoul (KR)

(72) Inventors: Jihee RYU, Paju-si (KR); Younghyun KO, Paju-si (KR); Jaeman JANG, Paju-si (KR)

(73) Assignee: LG Display Co., Ltd., Seoul (KR)

(21) Appl. No.: 19/352,793

(22) Filed: Oct. 8, 2025

(30) Foreign Application Priority Data
Dec. 31, 2024 (KR) 10-2024-0201861

(51) Int. Cl. H10D 30/67

(52) U.S. Cl. CPC H10D 30/6733

(57) ABSTRACT

A thin film transistor according to one or more examples includes an active layer having a channel portion, a gate insulating layer on the active layer, and a gate electrode on the gate insulating layer. The gate electrode includes a first gate electrode, and a second gate electrode. Each of the first gate electrode and the second gate electrode is spaced apart from the active layer and faces the active layer, the first gate electrode is in contact with the second gate electrode, and the first gate electrode has a work function different from a work function of the second gate electrode. A display apparatus including a thin film transistor is also disclosed.

### CROSS-REFERENCE TO RELATED APPLICATIONS

This application claims the benefit of and priority to Korean Patent Application No. 10-2024-0201861 filed on Dec. 31, 2024, the entire contents of which are incorporated herein by reference for all purposes as if fully set forth herein.

### BACKGROUND

### 1. Technical Field

The present disclosure relates to an apparatus and particularly to, for example, without limitation, a thin film transistor and a display apparatus comprising the same.

### 2. Description of Related Art

As a thin film transistor may be manufactured on a glass substrate or a plastic substrate, the thin film transistor is widely used as a switching element or a driving element of a display apparatus such as a liquid crystal display device or an organic light emitting device.

According to a material constituting an active layer, the thin film transistor may be divided into an amorphous silicon thin film transistor in which amorphous silicon is used as an active layer, a polycrystalline silicon thin film transistor in which polycrystalline silicon is used as an active layer, and an oxide semiconductor thin film transistor in which oxide semiconductor is used as an active layer.

Among them, the oxide semiconductor thin film transistor having high mobility and having a large resistance change according to the content of oxygen has the advantage of easiness in obtaining desired physical properties. In the process of manufacturing the oxide semiconductor thin film transistor, the oxide constituting the active layer may be a film at a relatively low temperature, whereby a manufacturing cost is low. Also, due to the properties of oxide, the oxide semiconductor is transparent, whereby it is advantageous to implement a transparent display.

The description of related art should not be considered prior art merely because it is mentioned in or associated with this section. The description of related art includes information that describes one or more aspects of the subject technology, and the description in this section does not limit the scope of the invention.

### SUMMARY

A high-resolution display device includes a large number of thin film transistors. In order to arrange a large number of thin film transistors in a predetermined area, the size of the thin film transistor should be reduced. However, the inventors of the present disclosure have recognized that when the size of the thin film transistor is reduced, a channel length is also shortened, whereby driving stability of the thin film transistor may be lowered or deteriorated, thereby deteriorating display quality of the display device.

Therefore, the inventors have conducted extensive research and experiments to reduce or suppress deterioration of a small-sized thin film transistor and to improve reliability.

In view of the foregoing problems and other limitations and disadvantages of the related art, an aspect of the present disclosure is directed to providing a technology for controlling a horizontal electric field intensity of a channel portion by using a plurality of gate electrodes having different work functions.

Another aspect of the present disclosure is directed to providing a thin film transistor which reduces or suppresses a degradation in a drain edge region due to a drain voltage by using a plurality of gate electrodes having different work functions.

Another aspect of the present disclosure is directed to providing a thin film transistor which improves driving stability by using a plurality of gate electrodes having different work functions.

A further aspect of the present disclosure is directed to providing a display apparatus including the thin film transistor.

In accordance with an aspect of the present disclosure, the above and other aspects may be accomplished by the provision of a thin film transistor comprising an active layer including a channel portion, a gate insulating layer on the active layer, and a gate electrode on the gate insulating layer, wherein the gate electrode includes a first gate electrode, and a second gate electrode, and wherein each of the first gate electrode and the second gate electrode is spaced apart from the active layer and faces the active layer, the first gate electrode is in contact with the second gate electrode, and the first gate electrode has a work function different from a work function of the second gate electrode.

The first gate electrode may have a first side and a second side opposite the first side, the second gate electrode may be in contact with the first side of the first gate electrode, and the second gate electrode may have a work function higher than that of the first gate electrode.

The difference between the work function of the second gate electrode and the work function of the first gate electrode may be 0.1 eV or more.

The first gate electrode may include any one of titanium (Ti), aluminum (Al), nickel (Ni), chromium (Cr), and copper (Cu), and the second gate electrode may include any one of gold (Au) and platinum (Pt).

The first gate electrode may include any one of titanium (Ti), aluminum (Al), and nickel (Ni), and the second gate electrode may include any one of chromium (Cr), copper (Cu), gold (Au), and platinum (Pt).

According to one example embodiment of the present disclosure, in an off state, a charge density of a region overlapping the second gate electrode in the channel portion and a charge density of a region overlapping the first gate electrode in the channel portion may be different from each other.

A charge density of a region overlapping the second gate electrode may be higher than a charge density of a region overlapping the first gate electrode.

According to one example embodiment of the present disclosure, in an on state, a horizontal electric field intensity of a region overlapping the second gate electrode and a horizontal electric field intensity of a region overlapping the first gate electrode in the channel portion may be different from each other.

In the channel portion, a horizontal electric field intensity of a region overlapping the second gate electrode may be smaller than a horizontal electric field intensity of a region overlapping the first gate electrode.

According to another example embodiment of the present disclosure, the first gate electrode may have a first side and a second side opposite the first side, the second gate electrode may be in contact with the second side of the first gate electrode, and the second gate electrode may have a work function lower than that of the first gate electrode.

The difference between the work function of the first gate electrode and the work function of the second gate electrode may be 0.1 eV or more.

The first gate electrode may include any one of gold (Au) and platinum (Pt), and the second gate electrode may include any one of titanium (Ti), aluminum (Al), nickel (Ni), chromium (Cr), and copper (Cu).

The first gate electrode may include any one of chromium (Cr), copper (Cu), gold (Au), and platinum (Pt), and the second gate electrode may include any one of titanium (Ti), aluminum (Al), and nickel (Ni).

According to another example embodiment of the present disclosure, the gate electrode may further include a third gate electrode, wherein the third gate electrode may be spaced apart from the active layer and may be disposed to face the active layer, the third gate electrode may be in contact with the second side of the first gate electrode, and the third gate electrode may have a work function lower than that of the second gate electrode.

The third gate electrode may have a work function lower than that of the first gate electrode.

The difference between the work function of the second gate electrode and the work function of the first gate electrode may be 0.1 eV or more, and the difference between the work function of the first gate electrode and the work function of the third gate electrode may be 0.1 eV or more.

The second gate electrode may include any one of gold (Au) and platinum (Pt), and each of the first gate electrode and the third gate electrode may include any one of titanium (Ti), aluminum (Al), nickel (Ni), chromium (Cr), and copper (Cu).

The second gate electrode may include any one of chromium (Cr) and copper (Cu), and each of the first gate electrode and the third gate electrode may include any one of titanium (Ti), aluminum (Al), and nickel (Ni).

The first gate electrode may include any one of chromium (Cr) and copper (Cu), the second gate electrode may include any one of gold (Au) and platinum (Pt), and the third gate electrode may include any one of titanium (Ti), aluminum (Al), and nickel (Ni).

According to another example embodiment of the present disclosure, in an off state, a charge density of a region overlapping the first gate electrode in the channel portion, a charge density of a region overlapping the second gate electrode in the channel portion, and a charge density of a region overlapping the third gate electrode in the channel portion may be different from one another.

In the channel portion, a charge density of a region overlapping the second gate electrode may be higher than a charge density of a region overlapping the first gate electrode, and a charge density of a region overlapping the first gate electrode may be higher than a charge density of a region overlapping the third gate electrode.

According to another example embodiment of the present disclosure, in an on state, a horizontal electric field intensity of a region overlapping the second gate electrode in the channel portion and a horizontal electric field intensity of a region overlapping the third gate electrode in the channel portion may be different from each other.

In the channel portion, a horizontal electric field intensity of a region overlapping the second gate electrode may be smaller than a horizontal electric field intensity of a region overlapping the third gate electrode.

According to another example embodiment of the present disclosure, it may provide a display apparatus including the thin film transistor.

In addition to the effects of the present disclosure as mentioned above, additional advantages and features of the present disclosure will be clearly understood by those skilled in the art from the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a plan view of a thin film transistor according to one example embodiment of the present disclosure;

FIG. 2 is a schematic cross-sectional view taken along line I-I′ of FIG. 1 according to one example embodiment of the present disclosure;

FIG. 3 is a schematic graph showing a charge density of an active layer of a thin film transistor according to a comparative example;

FIG. 4 is a schematic graph showing a charge density for each region of an active layer of a thin film transistor according to one example embodiment of the present disclosure;

FIG. 5 is an example graph showing a work function for each type of metal;

FIG. 6 is a schematic cross-sectional view of a thin film transistor according to another example embodiment of the present disclosure;

FIG. 7 is a schematic cross-sectional view of a thin film transistor according to another example embodiment of the present disclosure;

FIG. 8 is a schematic graph showing a charge density for each region of an active layer of a thin film transistor according to another example embodiment of the present disclosure;

FIG. 9 is a schematic cross-sectional view of a thin film transistor according to another example embodiment of the present disclosure;

FIG. 10 is a schematic view of a display apparatus according to another example embodiment of the present disclosure; and

FIG. 11 is an example circuit diagram of one pixel of FIG. 10.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure Further, the present disclosure is only defined by the scope of the claims.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. The terms of a singular form may include plural forms unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. These terms are used only to distinguish one element from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

Unless stated otherwise, the terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, unless stated otherwise, the terms “first direction,” “second direction,” and the like (e.g., an X-direction, a Y-direction, and Z-direction) should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “at least some portions,” “at least some parts,” “at least a portion,” “at least one or more portions,” “at least a given portion,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) multiple elements of the plurality of elements, or (v) all of the plurality of elements. Moreover, “at least some,” “at least some portions,” “at least some parts,” “at least a portion,” “at least one or more portions,” “at least a given portion,” “at least a part,” “at least one or more parts,” or the like of an element can represent (i) a portion (or a part) of the element, (ii) one or more portions (or parts) of the element, (iii) the element, or (iv) all portions of the element.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein. For example, the term “part” or “unit” may apply, for example, to a separate circuit, component or structure, an integrated circuit, a computational block of a circuit device, or a structure configured to perform a described function as should be understood by one of ordinary skill in the art.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like elements unless stated otherwise. The same or similar elements may be denoted by the same reference numerals even though they are depicted in different drawings. Repetitive descriptions of the same or similar elements may be omitted for brevity, and the descriptions provided for elements in one or more figures may also apply to elements in other figures that use the same reference numerals unless stated otherwise. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

In description of flow of a signal, for example, when a signal is provided from a node A to a node B, this may include a case where the signal is transferred from the node A to the node B via one or more nodes unless a phrase such as “immediately transferred,” “directly transferred” or the like is used.

In the embodiments of the present disclosure, a source electrode and a drain electrode are distinguished from each other, for convenience of explanation. However, the source electrode and the drain electrode are used interchangeably. Also, the source electrode in any one example embodiment of the present disclosure may be the drain electrode in another example embodiment of the present disclosure, and the drain electrode in any one example embodiment of the present disclosure may be the source electrode in another example embodiment of the present disclosure.

In one or more embodiments of the present disclosure, for convenience of explanation, a source connection portion is distinguished from a source electrode, and a drain connection portion is distinguished from a drain electrode. However, embodiments of the present disclosure are not limited to this structure. For example, a source connection portion may be a source electrode, and a drain connection portion may be a drain electrode. Also, a source connection portion may be a drain electrode, and a drain connection portion may be a source electrode.

In one or more embodiments of the present disclosure, a region in which the source electrode is in contact may be referred to as a source region, a region in which the drain electrode is in contact may be referred to as a drain region, and a region disposed between the source region and the drain region may be referred to as a channel region.

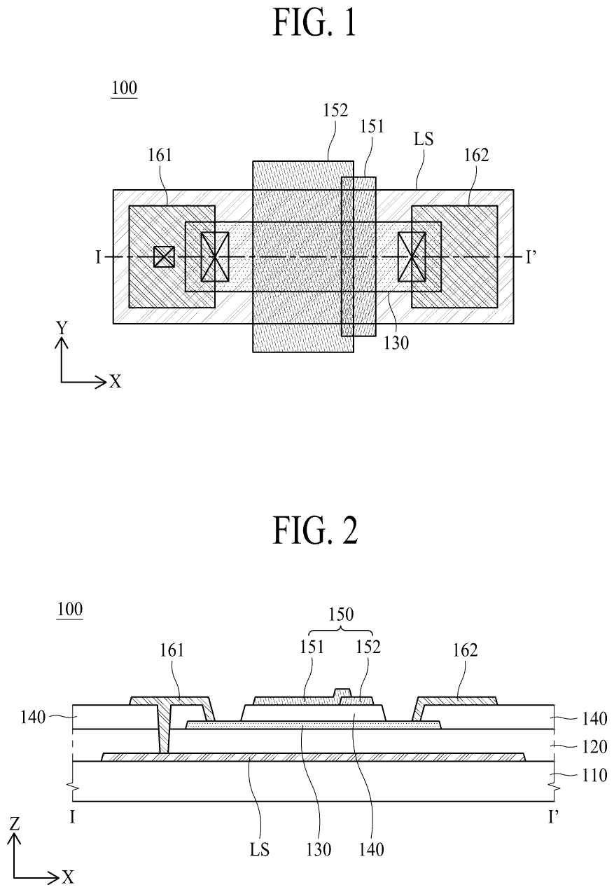

FIG. 1 is a plan view of a thin film transistor 100 according to one example embodiment of the present disclosure, and FIG. 2 is an example schematic cross-sectional view of the thin film transistor 100 taken along line I-I′ of FIG. 1.

Referring to FIGS. 1 and 2, the thin film transistor 100 according to one example embodiment of the present disclosure includes an active layer including a channel portion, a gate insulating layer on the active layer, and a gate electrode on the gate insulating layer. The gate electrode includes a first gate electrode and a second gate electrode. Each of the first gate electrode and the second gate electrode is spaced apart from the active layer and faces the active layer. The first gate electrode is in contact with the second gate electrode. The first gate electrode has a work function which is different from that of the second gate electrode.

Referring to FIG. 2, the thin film transistor 100 may be disposed on a substrate 110.

The substrate 110 supports components of the thin film transistor 100. Any structure supporting the thin film transistor 100 may be referred to as the substrate 110 without limitation.

A glass substrate or a polymer resin substrate may be used as the substrate 110. The polymer resin substrate may be a plastic substrate. The plastic substrate may include at least one having a flexible property of polyimide (PI), polycarbonate (PC), polyethylene (PE), polyester, polyethylene terephthalate (PET), and polystyrene (PS). When the plastic is used for the substrate 110, heat-resistant plastic capable of withstanding high temperatures may be used in consideration of a deposition process performed on the substrate 110 at a high temperature.

A light shielding layer LS may be disposed on the substrate 110. The light shielding layer LS may have a light blocking property. The light shielding layer LS may block light incident from the substrate 110, thereby protecting the channel portion 130n (see, e.g., FIG. 4) of the active layer 130.

The light shielding layer LS may be made of a material having the light blocking property. The light shielding layer LS may include at least one of aluminum-based metal such as aluminum (Al) or an aluminum alloy, molybdenum-based metal such as molybdenum (Mo) or molybdenum alloy, chromium (Cr), tantalum (Ta), neodymium (Nd), titanium (Ti), and iron (Fe).

According to one example embodiment of the present disclosure, the light shielding layer LS may have electrical conductivity. The light shielding layer LS may be electrically connected to any one of a source electrode 161 and a drain electrode 162. Referring to FIG. 2, for example, the light shielding layer LS may be connected to the source electrode 161.

A buffer layer 120 is disposed on the light shielding layer LS. The buffer layer 120 covers an upper surface of the substrate 110 and an upper surface of the light shielding layer LS. The buffer layer 120 has an insulating property and protects the active layer 130.

The buffer layer 120 may be formed of an inorganic material or an organic material. For example, the buffer layer 120 may include an insulating oxide such as silicon oxide (SiOx), aluminum oxide (Al₂O₃), or the like.

The buffer layer 120 may protect the active layer 130 by blocking impurities such as moisture and oxygen introduced from the substrate 110, may planarize an upper portion of the base substrate 110, and may be formed as a single layer or a plurality of layers.

Referring to FIG. 2, the active layer 130 may include the channel portion 130n, a source connection portion 131, and a drain connection portion 132 (see, e.g., FIG. 4). The source connection portion 131 may be in contact with the source electrode 161. The drain connection portion 132 may be in contact with the drain electrode 162.

The active layer 130 is disposed on the buffer layer 120 and includes an oxide semiconductor material. According to one example embodiment of the present disclosure, for example, the active layer 130 may be an oxide semiconductor layer made of an oxide semiconductor material.

For example, the active layer 130 may include at least one of IGZO(InGaZnO)-based oxide semiconductor material, IGO(InGaO)-based oxide semiconductor material, IGZTO(InGaZnSnO)-based oxide semiconductor material, GZTO(GaZnSnO)-based oxide semiconductor material, GZO(GaZnO)-based oxide semiconductor material, GO(GaO)-based oxide semiconductor material, TO(SnO)-based oxide semiconductor material, ITO(InSnO)-based oxide semiconductor material, ITZO(InSnZnO)-based oxide semiconductor material, IZO(InZnO)-based oxide semiconductor material, ZO(ZnO)-based oxide semiconductor material, IO(InO)-based oxide semiconductor material, InO(InO)-based oxide semiconductor material, ZnO-based oxide semiconductor material, and FIZO(FeInZnO)-based oxide semiconductor material.

The active layer 130 may have a single-layered structure or a multi-layered structure including two or more oxide semiconductor layers.

A gate insulating layer 140 is disposed on the active layer 130.

According to one example embodiment of the present disclosure, the gate insulating layer 140 may be disposed to cover the entire upper surface of the active layer 130. The gate insulating layer 140 may be disposed to cover an entire upper surface of the active layer 130 and may be disposed to cover an entire upper surface of the buffer layer 120.

The gate insulating layer 140 may be made of an insulating material including hydrogen (H). For example, the material for forming the gate insulating layer 140 may include hydrogen (H). Therefore, according to one example embodiment of the present disclosure, the gate insulating layer 140 may include hydrogen (H).

For example, the gate insulating layer 140 may include at least one of silicon oxide (SiOₓ), silicon nitride (SiNₓ), and aluminum oxide (AlOₓ).

The silicon oxide (SiOₓ) may be formed under a condition including silane (SiH₄) and oxygen (O₂). Accordingly, the gate insulating layer 140 including silicon oxide (SiOₓ) may include hydrogen.

The silicon nitride (SiNₓ) may be formed under a condition including silane (SiH₄), ammonia (NH₃), and oxygen (O₂). Accordingly, the gate insulating layer 140 including silicon nitride (SiNₓ) may include hydrogen.

The aluminum oxide (AlOₓ) may be formed under a condition including an aluminum compound, a hydroxyl group (OH), or moisture (H₂O). Accordingly, the gate insulating layer 140 including aluminum oxide (AlOₓ) may include hydrogen.

However, an embodiment of the present disclosure is not limited thereto, and other insulating materials generally known may be applied to the gate insulating layer 140.

According to one example embodiment of the present disclosure, a gate electrode 150 is disposed on the gate insulating layer 140. The gate electrode 150 is spaced apart from the active layer 130 and is configured to at least partially overlap the active layer 130. In the active layer 130, a portion overlapping the gate electrode 150 may be referred to as the channel portion.

The gate electrode 150 may include the first gate electrode 151 and the second gate electrode 152.

The first gate electrode 151 and the second gate electrode 152 may be spaced apart from the active layer 130 with respect to the gate insulating layer 140, respectively. More specifically, each of the first gate electrode 151 and the second gate electrode 152 may be spaced apart from the active layer 130 with respect to the gate insulating layer 140 and may be disposed to face the active layer 130.

The first gate electrode 151 may include a first side and a second side, wherein the second side is opposite to the first side. The first side of the first gate electrode 151 refers to a region facing a drain region with respect to the center of the first gate electrode 151. The second side of the first gate electrode 151 refers to a region facing a source region with respect to the center of the first gate electrode 151.

The first gate electrode 151 may be in contact with the second gate electrode 152. The first gate electrode 151 may be disposed in parallel with the second gate electrode 152 while being in contact with the second gate electrode 152. More specifically, the first side of the first gate electrode 151 may be disposed in parallel with the second gate electrode 152 while being in c ontact with the second gate electrode 152. Alternatively, the second side of the first gate electrode 151 may be disposed in parallel with the second gate electrode 152 while being in contact with the second gate electrode 152.

The first gate electrode 151 may be disposed to overlap at least a portion of the second gate electrode 152. More specifically, the first side of the first gate electrode 151 may be disposed to overlap the second gate electrode 152. Alternatively, the second side of the first gate electrode 151 may be disposed to overlap the second gate electrode 152.

Referring to FIG. 2, the first gate electrode 151 according to one example embodiment of the present disclosure may be formed to overlap at least a portion of the second gate electrode 152. More specifically, the first gate electrode 151 may be configured to overlap at least a portion of the second gate electrode 152 and may be formed on at least a portion of the second gate electrode 152.

The source electrode 161 and the drain electrode 162 are disposed on the gate insulating layer 140 while being spaced apart from the gate electrode 150. More specifically, the source electrode 161 may be disposed in the source region while being spaced apart from the gate electrode 150, and the drain electrode 162 may be disposed in the drain region while being spaced apart from the gate electrode 150.

The source electrode 161 and the drain electrode 162 are spaced apart from each other and are connected to the active layer 130, respectively. More specifically, the source electrode 161 and the drain electrode 162 may be formed on the gate insulating layer 140 while being spaced apart from each other with respect to the gate electrode 150 and may be connected to the active layer 130 through a contact hole, respectively.

Each of the source electrode 161 and the drain electrode 162 may include at least one of molybdenum (Mo), aluminum (Al), chrome (Cr), gold (Au), titanium (Ti), nickel (Ni), neodymium (Nd), copper (Cu), and an alloy thereof. Each of the source electrode 161 and the drain electrode 162 may be formed of a single layer made of metal or alloy thereof or may be formed of two or more layers.

An interlayer insulating layer (not shown) may be disposed on the gate electrode 150, the source electrode 161, and the drain electrode 162. Also, an interlayer insulating layer may be disposed in a contact hole region in which each of the source electrode 161 and the drain electrode 162 contacts the active layer 130. The interlayer insulating layer is an insulating layer formed of an insulating material. The interlayer insulating layer may be formed of an organic material, may be formed of an inorganic material or may be formed of a deposition structure of an organic material layer and an inorganic material layer.

According to one example embodiment of the present disclosure, the first gate electrode 151 may have a work function different from that of the second gate electrode 152.

The work function is the energy difference between the energy level that deviates from the electric force of material and the highest energy level (Fermi level) when electrons in the material are filled from the low energy level. For example, a work function of a metal is the minimum energy required to remove an electron from the Fermi level inside the metal to a point in the vacuum immediately outside the metal surface, where the electron is free from the influence of the bulk material of the metal. The unit of the work function is electronvolt (eV).

When the work function of the gate electrode 150 is different, the Fermi level is also different. Thus, even though the same voltage is applied thereto, the charge density in the channel portion 130n overlapping the gate electrode 150 may vary. Thus, the electric field formed in the channel portion 130n may vary.

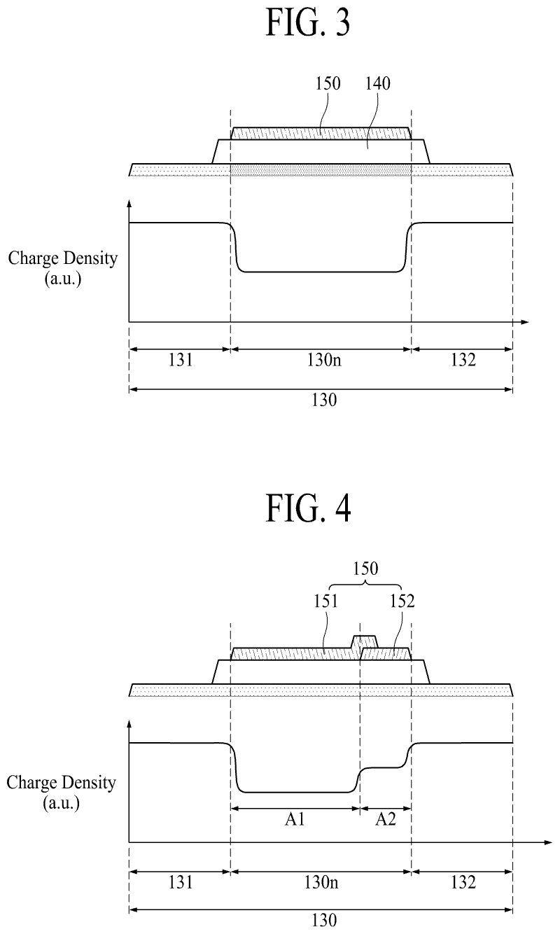

FIG. 3 is a schematic graph showing a charge density of an active layer when a thin film transistor according to a comparative example is in an off state (or turned-off).

According to one example embodiment of the present disclosure, in the channel portion 130n, a region adjacent to the source connection portion 131 may be defined as a source edge region, and a region adjacent to the drain connection portion 132 may be defined as a drain edge region.

Referring to FIG. 3, a thin film transistor according to a comparative example having a single gate electrode 150 has a large horizontal electric field in a source edge region and a drain edge region. Among these, since a high voltage is applied to a drain connection portion 132, a stress by the voltage is severe in the drain edge region between the drain connection portion 132 and a channel portion 130n. Accordingly, in the thin film transistor according to a comparative example, the drain edge region may be deteriorated. When the thin film transistor is included in a display apparatus, it may have problems related with deterioration of display quality or lifespan reduction in the display apparatus.

On the other hand, the thin film transistor 100 according to one example embodiment of the present disclosure includes the second gate electrode 152 having a work function different from that of the first gate electrode 151. More specifically, the second gate electrode 152 may contact the first side of the first gate electrode 151 and may have the work function which is higher than that of the first gate electrode 151.

FIG. 4 is a schematic graph showing a charge density for each region of the active layer 130 when the thin film transistor 100 according to one example embodiment of the present disclosure is in an off state.

Referring to FIG. 4, when the thin film transistor 100 according to one example embodiment of the present disclosure is in an off state, a charge density of a region A2 overlapping the second gate electrode 152 in the channel portion 130n may be different from a charge density of a region A1 overlapping the first gate electrode 151 in the channel portion 130n. More specifically, when the thin film transistor 100 according to one example embodiment of the present disclosure is in the off state, the charge density of the region A2 overlapping the second gate electrode 152 in the channel portion 130n may be higher than the charge density of the region A1 overlapping the first gate electrode 151 in the channel portion 130n.

When the thin film transistor 100 according to one example embodiment of the present disclosure having the charge density is in an on state (or turned-on), a horizontal electric field intensity of the region A2 overlapping the second gate electrode 152 having the large charge density may be different from a horizontal electric field intensity of the region A1 overlapping the first gate electrode 151. More specifically, when the thin film transistor 100 is in the on state, the horizontal electric field intensity of the region A2 overlapping the second gate electrode 152 having the large charge density may be relatively smaller than the horizontal electric field intensity of the region A1 overlapping the first gate electrode 151. Accordingly, even when the large voltage is applied to the drain connection portion 132, a stress by the voltage in the drain edge region between the drain connection portion 132 and the channel portion 130n may be reduced. Thus, the degradation of the drain edge region by the drain voltage may be reduced or suppressed. When the thin film transistor 100 is included in the display apparatus 500, the display apparatus 500 may have excellent display quality and long lifespan property.

According to one example embodiment of the present disclosure, the difference between the work function of the second gate electrode 152 and the work function of the first gate electrode 151 may be 0.1 eV or more.

More specifically, the difference between the work function of the second gate electrode 152 and the work function of the first gate electrode 151 may be 0.1 eV or more, may be 0.2 eV or more, may be 0.3 eV or more, may be 0.4 eV or more or may be 0.5 eV or more.

According to one example embodiment of the present disclosure, when the second gate electrode 152 has a work function higher than the first gate electrode 151 by more than 0.1 eV, the degradation in the drain edge region by the drain voltage may be reduced or suppressed.

When the difference between the work function of the second gate electrode 152 and the work function of the first gate electrode 151 is less than 0.1 eV, it may be difficult to reduce or suppress the degradation in the drain edge region by the drain voltage.

According to one example embodiment of the present disclosure, the gate electrode 150 may include at least one of titanium (Ti), aluminum (Al), nickel (Ni), chromium (Cr), copper (Cu), gold (Au), and platinum (Pt).

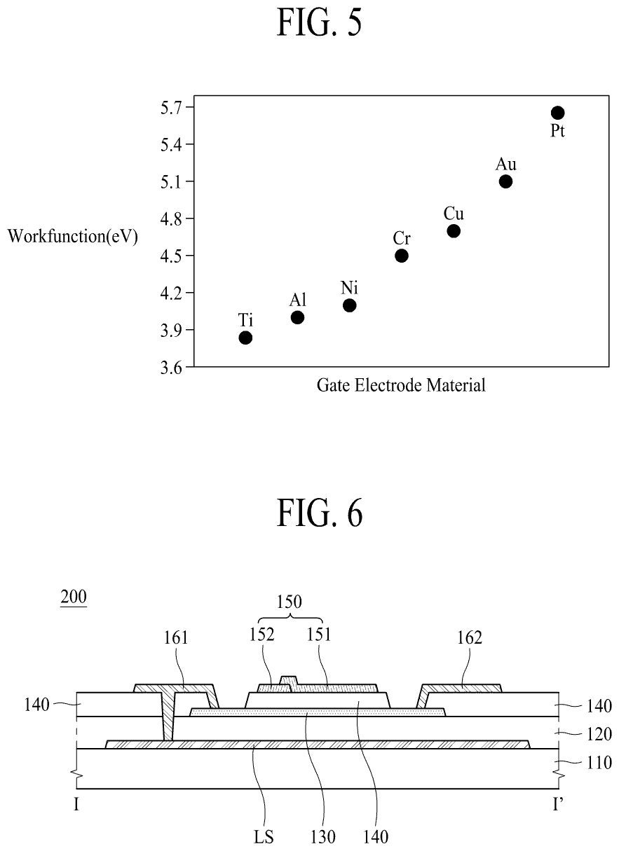

FIG. 5 is an example work function graph for each type of metal measured by a Kelvin Probe Measurement (KPM) method.

Referring to FIG. 5, it may show the difference of the work function among titanium (Ti), aluminum (Al), nickel (Ni), chromium (Cr), copper (Cu), gold (Au), and platinum (Pt).

According to one example embodiment of the present disclosure, the second gate electrode 152 may be designed to include metal having a work function higher than that of the first gate electrode 151 so as to reduce or suppress the occurrence of deterioration in the drain edge region by the drain voltage.

According to one example embodiment of the present disclosure, the first gate electrode 151 may include any one of titanium (Ti), aluminum (Al), nickel (Ni), chromium (Cr), and copper (Cu), and the second gate electrode 152 may include any one of gold (Au) and platinum (Pt).

According to one example embodiment of the present disclosure, the first gate electrode 151 may include any one metal of titanium (Ti), aluminum (Al), and nickel (Ni), and the second gate electrode 152 may include any one metal of chromium (Cr), copper (Cu), gold (Au), and platinum (Pt).

However, a description of a combination of the metal included in the first gate electrode 151 and the second gate electrode 152 is an example, and the present disclosure is not limited thereto.

FIG. 6 is a schematic cross-sectional view of a thin film transistor 200 according to another example embodiment of the present disclosure.

Hereinafter, in order to avoid redundancy, the descriptions of the foregoing components may be omitted or may be described briefly. In this regard, the descriptions provided for the components according to one or more examples of the present disclosure may apply to the components shown in FIG. 6 that use the same or similar reference numerals unless stated otherwise.

Referring to FIG. 6, the thin film transistor 200 according to another example embodiment of the present disclosure may include a first gate electrode 151 and a second gate electrode 152, and the second gate electrode 152 may be in contact with a second side of the first gate electrode 151. The second gate electrode 152 may have a work function lower than that of the first gate electrode 151.

Referring to FIG. 6, for example, when the second gate electrode 152 contacting the second side of the first gate electrode 151 has a work function lower than that of the first gate electrode 151, the first gate electrode 151 has a work function higher than that of the second gate electrode 152. Therefore, in the thin film transistor 200 according to another example embodiment of the present disclosure, a horizontal electric field intensity in a drain edge region may be reduced. Accordingly, the degradation occurrence in the drain edge region by the drain voltage may be reduced or suppressed.

According to another example embodiment of the present disclosure, the difference between the work function of the first gate electrode 151 and the work function of the second gate electrode 152 may be 0.1 eV or more.

More specifically, the difference between the work function of the first gate electrode 151 and the work function of the second gate electrode 152 may be 0.1 eV or more, may be 0.2 eV or more, may be 0.3 eV or more, may be 0.4 eV or more or may be 0.5 eV or more.

When the difference between the work function of the first gate electrode 151 and the work function of the second gate electrode 152 is less than 0.1 eV, it may be difficult to reduce or suppress an occurrence of deterioration in the drain edge region by the drain voltage.

According to another example embodiment of the present disclosure, the first gate electrode 151 may be designed to include metal having a work function higher than that of the second gate electrode 152 so as to reduce or suppress the occurrence of deterioration in the drain edge region by the drain voltage.

For example, the first gate electrode 151 may include metal having a work function higher than that of the second gate electrode 152 in the metal of FIG. 5. More specifically, the first gate electrode 151 may include metal having a work function higher than that of the second gate electrode 152 in the metal of FIG. 5.

According to another example embodiment of the present disclosure, the first gate electrode 151 may include any one of gold (Au) and platinum (Pt), and the second gate electrode 152 may include any one of titanium (Ti), aluminum (Al), nickel (Ni), chromium (Cr), and copper (Cu).

According to another example embodiment of the present disclosure, the first gate electrode 151 may include any one metal of chromium (Cr), copper (Cu), gold (Au), and platinum (Pt), and the second gate electrode may include any one metal of titanium (Ti), aluminum (Al), and nickel (Ni).

However, a description of a combination of the metal included in the first gate electrode 151 and the second gate electrode 152 is an example, and the present disclosure is not limited thereto.

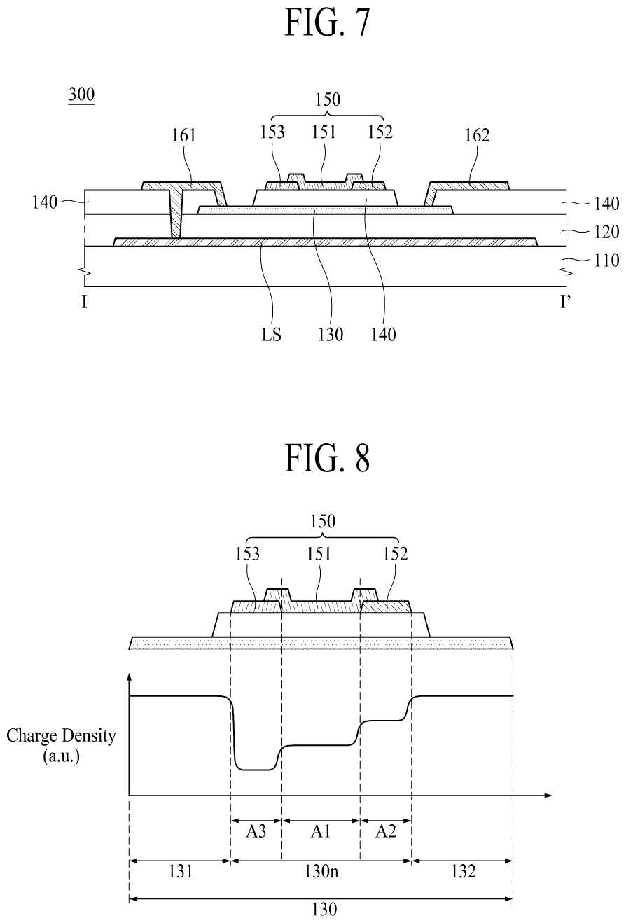

FIG. 7 is a schematic cross-sectional view of a thin film transistor 300 according to another example embodiment of the present disclosure.

The thin film transistor 300 according to another example embodiment of the present disclosure may further include a third gate electrode 153 in addition to a first gate electrode 151 and a second gate electrode 152.

Each of the first gate electrode 151, the second gate electrode 152, and the third gate electrode 153 may be spaced apart from an active layer 130 with respect to a gate insulating layer 140. More specifically, each of the first gate electrode 151, the second gate electrode 152, and the third gate electrode 153 may be spaced apart from the active layer 130 with respect to the gate insulating layer 140 while being opposite to the active layer 130.

The first gate electrode 151 may be in contact with the second gate electrode 152. The first gate electrode 151 may be disposed in parallel with the second gate electrode 152 while being in contact with the second gate electrode 152. More specifically, a first side of the first gate electrode 151 may be disposed in parallel with the second gate electrode 152 while being in contact with the second gate electrode 152.

The first gate electrode 151 may be disposed to overlap at least a portion of the second gate electrode 152. More specifically, the first side of the first gate electrode 151 may be disposed to overlap the second gate electrode 152.

The third gate electrode 153 may be in contact with the first gate electrode 151. The third gate electrode 153 may be disposed in parallel with the first gate electrode 151 while being in contact with the first gate electrode 151. More specifically, the third gate electrode 153 may be disposed in parallel in contact with a second side of the first gate electrode 151.

The third gate electrode 153 may be disposed to overlap at least a portion of the first gate electrode 151. More specifically, the third gate electrode 153 may be disposed to overlap the second side of the first gate electrode 151.

According to another example embodiment of the present disclosure, the second gate electrode 152 may have a work function higher than that of the first gate electrode 151, and the second gate electrode 153 may have a work function higher than that of the third gate electrode 153.

FIG. 8 is a schematic graph showing a charge density for each region of the active layer 130 when the thin film transistor 300 according to another example embodiment of the present disclosure is in an off state.

Referring to FIG. 8, when the thin film transistor 300 according to another example embodiment of the present disclosure is in an off state, in a channel portion 130n, a charge density of a region A1 overlapping the first gate electrode 151, a charge density of a region A2 overlapping the second gate electrode 152, and a charge density of a region A3 overlapping the third gate electrode 153 may be different from one another. More specifically, when the thin film transistor 300 according to another example embodiment of the present disclosure is in the off state, in the channel portion 130n, the charge density of the region A2 overlapping the second gate electrode 152 may be higher than the charge density of the region A1 overlapping the first gate electrode 151, and the charge density of the region A1 overlapping the first gate electrode 151 may be higher than the charge density of the region A3 overlapping the third gate electrode 153.

When the thin film transistor 300 according to another example embodiment of the present disclosure having the charge density is in the on state, a horizontal electric field intensity of the region A2 overlapping the second gate electrode 152 having the large charge density may be different from a horizontal electric field intensity of the region A3 overlapping the third gate electrode 153. More specifically, when the thin film transistor 100 is in the on state, the horizontal electric field intensity of the region A2 overlapping the second gate electrode 152 having the large charge density may be relatively smaller than the horizontal electric field intensity of the region A3 overlapping the third gate electrode 153. Accordingly, even when a large voltage is applied to a drain connection portion 132, a stress by the voltage in a drain edge region between the drain connection portion 132 and the channel portion 130n may be reduced. Thus, the degradation of the drain edge region by the drain voltage may be reduced or suppressed. When the thin film transistor 300 is included in a display apparatus 500, the display apparatus 500 may have excellent display quality and long lifespan property.

According to another example embodiment of the present disclosure, the third gate electrode 153 may have a work function lower than that of the first gate electrode 151.

According to another example embodiment of the present disclosure, in the channel portion 130n, the region A3 overlapping the third gate electrode 153 has a predetermined horizontal electric field. More specifically, the horizontal electric field intensity of the region A3 overlapping the third gate electrode 153 is relatively larger than the horizontal electric field intensity of the region A2 overlapping the second gate electrode. However, since a voltage lower than that of the drain connection portion 132 is applied to a source connection portion 131, a stress due to the voltage is small in a source edge region between the source connection portion 131 and the channel portion 130n. Therefore, in the thin film transistor 300 according to another example embodiment of the present disclosure, the deterioration in the source edge region may not occur.

According to another example embodiment of the present disclosure, in the channel portion 130n, since the region A3 overlapping the third gate electrode 153 has a low charge density, it may perform the same function as the channel portion 130n in all regions except for a partial region adjacent to the source connection portion 131. In the channel portion 130n, the region A3 overlapping the third gate electrode 153 may perform the same function as the channel portion 130n in all regions except for a partial region adjacent to the source connection portion 131, whereby it may have an effect of increasing an effective channel length. In an aspect, an effective channel length may refer to a length of the conductive channel under the control of the gate electrode, and current may flow through the channel when the thin film transistor is in an on state (or is turned on). It may represent the actual length of the conductive channel that is controlled by the gate electrode during operation, and it may differ from the physical or drawn gate length.

In addition, since the region A3 overlapping the third gate electrode 153 has a low charge density, an effect of increasing a threshold voltage may be generated, and a negative shift (minus shift (−)) of the threshold voltage may be prevented or reduced. Therefore, as the thin film transistor 300 according to another example embodiment of the present disclosure includes the third gate electrode 153 having a work function lower than that of the first gate electrode 151, driving stability may be improved.

According to another example embodiment of the present disclosure, the difference between the work function of the second gate electrode 152 and the work function of the first gate electrode 151 may be 0.1 eV or more.

More specifically, the difference between the work function of the second gate electrode 152 and the work function of the first gate electrode 151 may be 0.1 eV or more, may be 0.2 eV or more, may be 0.3 eV or more, may be 0.4 eV or more or may be 0.5 eV or more.

According to another example embodiment of the present disclosure, when the second gate electrode 152 has a work function higher than the first gate electrode 151 by more than 0.1 eV, the degradation in the drain edge region by the drain voltage may be reduced or suppressed.

When the difference between the work function of the second gate electrode 152 and the work function of the first gate electrode 151 is less than 0.1 eV, it may be difficult to reduce or suppress the degradation in the drain edge region by the drain voltage.

According to another example embodiment of the present disclosure, the difference between the work function of the first gate electrode 151 and the work function of the third gate electrode 153 may be 0.1 eV or more.

More specifically, the difference between the work function of the first gate electrode 151 and the work function of the third gate electrode 153 may be 0.1 eV or more, may be 0.2 eV or more, may be 0.3 eV or more, may be 0.4 eV or more or may be 0.5 eV or more.

According to another example embodiment of the present disclosure, when the third gate electrode 153 has a work function lower than the first gate electrode 151 by more than 0.1 eV, the region A3 of the channel portion 130n overlapping the third gate electrode 153 has a low charge density, whereby it may perform the same function as the channel portion 130n in all regions except for a partial region adjacent to the source connection portion 131.

In addition, since the region A3 overlapping the third gate electrode 153 has a low charge density, an effect of increasing a threshold voltage may be generated, and a negative shift (minus shift (−)) of the threshold voltage may be prevented or reduced. Therefore, as the thin film transistor 300 according to another example embodiment of the present disclosure includes the third gate electrode 153 having a work function lower than that of the first gate electrode 151 by more than 0.1 eV, driving stability may be improved.

When the difference between the work function of the first gate electrode 151 and the work function of the third gate electrode 153 is less than 0.1 eV, the threshold voltage may not be sufficiently high.

According to another example embodiment of the present disclosure, the second gate electrode 152 may be designed to include metal having a work function higher than that of the first gate electrode 151 and the third gate electrode 153 in order to reduce or suppress the occurrence of deterioration in the drain edge region by the drain voltage.

According to another example embodiment of the present disclosure, the second gate electrode 152 may include any one metal of gold (Au) and platinum (Pt), and each of the first gate electrode 151 and the third gate electrode 153 may include any one metal of titanium (Ti), aluminum (Al), nickel (Ni), chromium (Cr), and copper (Cu).

According to another example embodiment of the present disclosure, the second gate electrode 152 may include any one metal of chromium (Cr), copper (Cu), gold (Au), and platinum (Pt), and each of the first gate electrode 151 and the third gate electrode 153 may include any one metal of titanium (Ti), aluminum (Al), and nickel (Ni).

According to another example embodiment of the present disclosure, the third gate electrode 153 may include metal having a work function lower than that of the first gate electrode 151 so as to prevent or reduce the negative shift (minus shift (−)) of the threshold voltage by the increase in the threshold voltage.

According to another example embodiment of the present disclosure, the second gate electrode 152 may include any one metal of gold (Au) and platinum (Pt), the first gate electrode 151 may include any one metal of chromium (Cr) and copper (Cu), and the third gate electrode 153 may include any one metal of titanium (Ti), aluminum (Al), and nickel (Ni).

However, a description of a combination of the metal included in the first gate electrode 151, the second gate electrode 152, and the third gate electrode 153 is an example, and the present disclosure is not limited thereto.

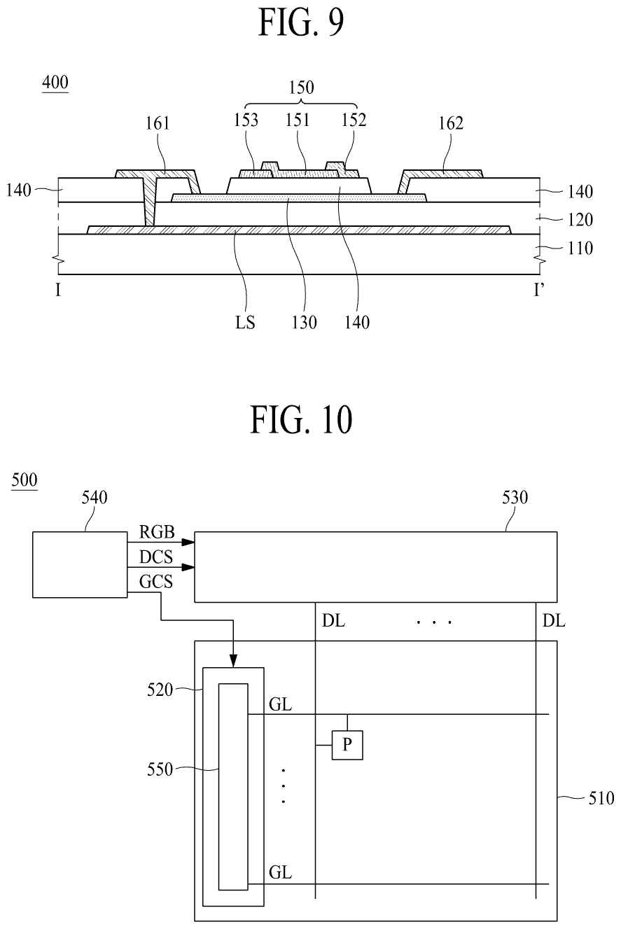

FIG. 9 is a schematic cross-sectional view of a thin film transistor 400 according to another example embodiment of the present disclosure. In order to avoid redundancy, repetitive descriptions of the components may be omitted or may be described briefly. In this regard, the descriptions provided for the components shown in FIG. 7 may apply to the components shown in FIG. 9 that use the same or similar reference numerals unless stated otherwise.

Referring to FIG. 9, the thin film transistor 400 according to another example embodiment of the present disclosure may include a first gate electrode 151, a second gate electrode 152, and a third gate electrode 153. The second gate electrode 152 may contact a first side of the first gate electrode 151 and may have a work function higher than that of the first gate electrode 151. The third gate electrode 153 may contact a second side of the first gate electrode 151 and may have a work function lower than that of the first gate electrode 151.

According to another example embodiment of the present disclosure, at least a portion of the first gate electrode 151 may be formed to overlap at least a portion of the third gate electrode 153. In addition, at least a portion of the second gate electrode 152 may be formed to overlap at least a portion of the first gate electrode 151.

Accordingly, the thin film transistor 400 according to another example embodiment of the present disclosure may reduce or suppress the degradation in the drain edge region by the drain voltage and may improve driving stability.

Another example embodiment of the present disclosure provides a display apparatus 500 including at least one of the thin film transistors 100, 200, 300, and 400 described above.

FIG. 10 is a schematic diagram of a display apparatus 500 according to another example embodiment of the present disclosure.

As shown in FIG. 10, the display apparatus 500 according to another example embodiment of the present disclosure includes a display panel 510, a gate driver 520, a data driver 530, and a controller 540.

Gate lines GL and data lines DL are disposed in the display panel 510, and a pixel P is disposed in each crossing region of the gate lines GL and the data lines DL. An image is displayed by driving the pixel P.

The controller 540 controls the gate driver 520 and the data driver 530.

The controller 540 outputs a gate control signal GCS for controlling the gate driver 520 and a data control signal DCS for controlling the data driver 530 by using a signal supplied from an external system. In addition, the controller 540 samples input image data input from the external system, rearranges the sampled input image data, and supplies the rearranged digital image data RGB to the data driver 530.

The gate control signal GCS includes a gate start pulse GSP, a gate shift clock GSC, a gate output enable signal GOE, a start signal Vst, and a gate clock GCLK. In addition, control signals for controlling a shift register 550 may be included in the gate control signal GCS.

The data control signal DCS includes a source start pulse SSP, a source shift clock signal SSC, a source output enable signal SOE, and a polarity control signal POL.

The data driver 530 supplies a data voltage to the data lines DL of the display panel 510. Specifically, the data driver 530 converts the image data RGB provided from the controller 540 into an analog data voltage and supplies the analog data voltage to the data lines DL.

The gate driver 520 may include the shift register 550.

The shift register 550 sequentially supplies a gate pulse to the gate lines GL during one frame by using the start signal and the gate clock transmitted from the controller 540. Herein, one frame refers to a period in which one image is output through the display panel 510. The gate pulse has a turn-on voltage capable of turning on a switching element (thin film transistor) disposed in the pixel P.

In addition, the shift register 550 supplies a gate-off signal capable of turning off the switching element to the gate line GL during the remaining period in which the gate pulse is not supplied in one frame. Hereinafter, the gate pulse and the gate-off signal are collectively referred to as a scan signal SS or Scan.

According to one example embodiment of the present disclosure, the gate driver 520 may be provided on the substrate 110. As described above, a structure in which the gate driver 520 is directly provided on the substrate 110 is referred to as a gate-in-panel GIP structure. The gate driver 520 may include at least one of the thin film transistors 100, 200, 300, and 400 described above.

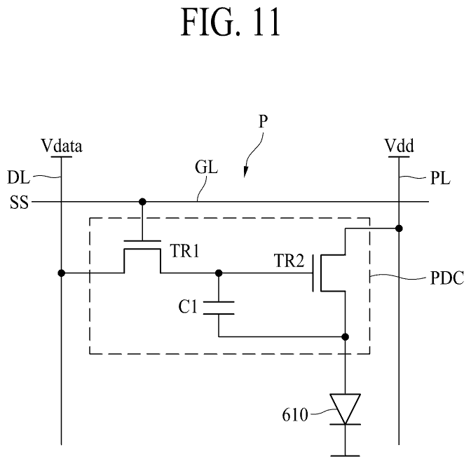

FIG. 11 is an example circuit diagram of any one pixel P of FIG. 10.

The circuit diagram of FIG. 11 is an equivalent circuit diagram of the pixel P of the display apparatus 500 including an organic light emitting diode OLED as a display device 610.

The pixel P includes the display device 610 and a pixel driver PDC for driving the display device 610.

The display apparatus 500 according to another example embodiment of the present disclosure may include at least one of the thin film transistors 100, 200, 300, and 400 described above. Any one of the thin film transistors 100, 200, 300, and 400 described above may be used as a first thin film transistor TR1 or a second thin film transistor TR2 of FIG. 11.

The first thin film transistor TR1 is connected to the gate line GL and the data line DL, and is turned on or off by the scan signal SS supplied through the gate line GL.

The data line DL provides the data voltage Vdata to the pixel driver PDC, and the first thin film transistor TR1 controls the application of the data voltage Vdata.

A driving power line PL provides a driving voltage Vdd to the display device 610, and the second thin film transistor TR2 controls the driving voltage Vdd. The driving voltage Vdd is a pixel driving voltage for driving the organic light emitting diode OLED corresponding to the display device 610.

When the first thin film transistor TR1 is turned on by the scan signal SS applied from the gate driver 520 through the gate line GL, the data voltage Vdata supplied through the data line DL is supplied to a gate electrode of the second thin film transistor TR2 connected to the display device 610. The data voltage Vdata is charged in a first capacitor C1 formed between a source electrode and the gate electrode of the second thin film transistor TR2. The first capacitor C1 is a storage capacitor Cst.

The amount of current supplied to the organic light emitting diode OLED corresponding to the display device 610 through the second thin film transistor TR2 is controlled according to the data voltage Vdata, whereby it is possible to control the grayscale of light output from the display device 610.

Various examples of the present disclosure are described below. These are provided as examples, and do not limit the scope of the present disclosure.

In one or more examples, at least a portion of the second gate electrode is disposed on, or below, at least a portion of the first gate electrode along a first direction. In one or more examples, the at least a portion of the second gate electrode is disposed directly on, or directly below, the at least a portion of the first gate electrode along the first direction.

In one or more examples, each of at least another portion of the second gate electrode and at least another portion of the first gate electrode is disposed on (or stacked on) the gate insulating layer along the first direction. In one or more examples, each of the at least another portion of the second gate electrode and the at least another portion of the first gate electrode is disposed directly on (or stacked directly on) the gate insulating layer along the first direction. For example, the at least another portion of the second gate electrode is disposed directly on the gate insulating layer along the first direction, without the first gate electrode disposed between the at least another portion of the second gate electrode and the gate insulating layer. For example, the at least another portion of the first gate electrode is disposed directly on the gate insulating layer along the first direction, without the second gate electrode disposed between the at least another portion of the first gate electrode and the gate insulating layer.

In one or more examples, the at least another portion of the second gate electrode overlaps the at least another portion of the first gate electrode along the first direction.

In one or more examples, the at least a portion of the second gate electrode overlaps the at least a portion of the first gate electrode along the second direction, along the third direction, or along the second and third directions.

In one or more examples, the first direction is a Z-direction, the second direction is a Y-direction, and the third direction is an X-direction. In one or more examples, the first, second and third directions are perpendicular to one another.

For example, the first direction is perpendicular to a first plane defined by the active layer or the gate insulating layer. For example, the first direction is not parallel to the first plane, and is perpendicular to a direction in which current flows when the thin film transistor is in an on state. For example, the first direction is not parallel to the first plane, and is perpendicular to a direction in which a length of the active layer extends or in which a channel length extends.

For example, the second direction is parallel to a direction in which a width of the active layer extends. For example, the second direction is parallel to the first plane, and is perpendicular to the direction in which current flows when the thin film transistor is in an on state. For example, the second direction is parallel to the first plane, and is perpendicular to the direction in which the length of the active layer extends or in which the channel length extends.

For example, the third direction is parallel to the direction in which current flows when the thin film transistor is in an on state. For example, the third direction is parallel to the direction in which the length of the active layer extends or in which the channel length extends.

In one or more examples, only a portion (not an entirety) of the second gate electrode overlaps only a portion (not an entirety) of the first gate electrode along the second direction, along the third direction, or along the second and third directions. In one or more examples, only another portion (not an entirety) of the second gate electrode overlaps only another portion (not an entirety) of the first gate electrode along the first direction.

In one or more examples, at least a portion of the second gate electrode is disposed on, or below, at least a portion of the first gate electrode along the first direction; and at least a given portion of the third gate electrode is disposed on, or below, at least a given portion of the first gate electrode along the first direction. In one or more examples, the at least a portion of the second gate electrode is disposed directly on, or directly below, the at least a portion of the first gate electrode along the first direction, and the at least a given portion of the third gate electrode is disposed directly on, or directly below, the at least a given portion of the first gate electrode along the first direction.

In one or more examples, each of at least another portion of the third gate electrode, the at least another portion of the second gate electrode, and the at least another portion of the first gate electrode is disposed on the gate insulating layer along the first direction. In one or more examples, each of the at least another portion of the third gate electrode, the at least another portion of the second gate electrode, and the at least another portion of the first gate electrode is disposed directly on the gate insulating layer along the first direction.

In one or more examples, the at least another portion of the second gate electrode and the at least another portion of the first gate electrode overlap along the first direction. In one or more examples, the at least another portion of the third gate electrode and the at least another portion of the first gate electrode overlap along the first direction.

In one or more examples, the at least a portion of the second gate electrode and the at least a portion of the first gate electrode overlap along the second direction, along the third direction, or along the second and third directions. In one or more examples, the at least a given portion of the third gate electrode and the at least a given portion of the first gate electrode overlap along the second direction, along the third direction, or along the second and third directions.

In one or more examples, only a given portion (not an entirety) of the third gate electrode overlaps only a given portion (not an entirety) of the first gate electrode along the second direction, along the third direction, or along the second and third directions. In one or more examples, only another portion (not an entirety) of the third gate electrode overlaps only another portion (not an entirety) of the first gate electrode along the first direction.

In one or more examples, the first gate electrode and the second gate electrode comprise different materials.

In one or more examples, the first gate electrode and the third gate electrode comprise different materials.

In one or more examples, the second gate electrode and the third gate electrode comprise different materials.

As the display apparatus 500 according to another example embodiment of the present disclosure includes at least one of the thin film transistors 100, 200, 300, and 400, the display apparatus 500 may have excellent display quality or long lifespan property, and driving stability may be improved.

As the thin film transistor according to one example embodiment of the present disclosure includes the second gate electrode which contacts the first side of the first gate electrode and has the work function higher than that of the first gate electrode, it is possible to control the horizontal electric field intensity in the drain edge region.

As the horizontal electric field intensity of the drain edge region is controlled in the thin film transistor according to one example embodiment of the present disclosure, the occurrence of deterioration in the drain edge region by the drain voltage may be reduced or suppressed.

As the thin film transistor according to another example embodiment of the present disclosure further includes the third gate electrode which contacts the second side of the first gate electrode and has the work function lower than that of the first gate electrode, it may have an effect of increasing an effective channel length.

As the effect of increasing the threshold voltage is provided in the thin film transistor according to another example embodiment of the present disclosure, driving stability may be improved.

As the display apparatus according to another example embodiment of the present disclosure may include the above-described thin film transistor. Thus, the display apparatus according to another example embodiment of the present disclosure may have excellent display quality or long lifespan property.

It will be apparent to those skilled in the art that various substitutions, modifications, and variations are possible within the scope of the present disclosure without departing from the technical idea and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A thin film transistor, comprising:
an active layer including a channel portion;
a gate insulating layer on the active layer; and
a gate electrode on the gate insulating layer,
wherein the gate electrode includes:
a first gate electrode; and
a second gate electrode, and
wherein:
each of the first gate electrode and the second gate electrode is spaced apart from the active layer and faces the active layer;
the first gate electrode is in contact with the second gate electrode; and
the first gate electrode has a work function different from a work function of the second gate electrode.

2. The thin film transistor of claim 1, wherein:
the first gate electrode has a first side and a second side opposite the first side;
the second gate electrode is in contact with the first side of the first gate electrode; and
the work function of the second gate electrode is higher than the work function of the first gate electrode.

3. The thin film transistor of claim 2,
wherein a difference between the work function of the second gate electrode and the work function of the first gate electrode is equal to or greater than 0.1 eV.

4. The thin film transistor of claim 2, wherein:
the first gate electrode includes any one of titanium, aluminum, nickel, chromium, and copper; and
the second gate electrode includes any one of gold and platinum.

5. The thin film transistor of claim 2, wherein:
the first gate electrode includes any one of titanium, aluminum, and nickel; and
the second gate electrode includes any one of chromium, copper, gold, and platinum.

6. The thin film transistor of claim 1,
wherein in case of an off state, a charge density of a region overlapping the second gate electrode is higher than a charge density of a region overlapping the first gate electrode.

7. The thin film transistor of claim 1,
wherein, in case of an on state, in the channel portion, a horizontal electric field intensity of a region overlapping the second gate electrode is smaller than a horizontal electric field intensity of a region overlapping the first gate electrode.

8. The thin film transistor of claim 1, wherein:
the first gate electrode has a first side and a second side opposite the first side;
the second gate electrode is in contact with the second side of the first gate electrode; and
the work function of the second gate electrode is lower than the work function of the first gate electrode.

9. The thin film transistor of claim 8,
wherein a difference between the work function of the first gate electrode and the work function of the second gate electrode is equal to or greater than 0.1eV.

10. The thin film transistor of claim 8, wherein:
the first gate electrode includes any one of gold and platinum; and
the second gate electrode includes any one of titanium, aluminum, nickel, chromium, and copper.

11. The thin film transistor of claim 8, wherein:
the first gate electrode includes any one of chromium, copper, gold, and platinum; and
the second gate electrode includes any one of titanium, aluminum, and nickel.

12. The thin film transistor of claim 2, wherein:
the gate electrode further includes a third gate electrode;
the third gate electrode is spaced apart from the active layer and faces the active layer;
the third gate electrode is in contact with the second side of the first gate electrode; and
a work function of the third gate electrode is lower than the work function of the second gate electrode.

13. The thin film transistor of claim 12,
wherein the work function of the third gate electrode is lower than the work function of the first gate electrode.

14. The thin film transistor of claim 12, wherein:
a difference between the work function of the second gate electrode and the work function of the first gate electrode is equal to or greater than 0.1 eV; and
a difference between the work function of the first gate electrode and the work function of the third gate electrode is equal to or greater than 0.1 eV.

15. The thin film transistor of claim 12, wherein:
the second gate electrode includes any one of gold and platinum; and
each of the first gate electrode and the third gate electrode includes any one of titanium, aluminum, nickel, chromium, and copper.

16. The thin film transistor of claim 12, wherein:
the second gate electrode includes any one of chromium and copper; and
each of the first gate electrode and the third gate electrode includes any one of titanium, aluminum, and nickel.

17. The thin film transistor of claim 12, wherein:
the first gate electrode includes any one of chromium and copper;
the second gate electrode includes any one of gold and platinum; and
the third gate electrode includes any one of titanium, aluminum, and nickel.

18. The thin film transistor of claim 12, wherein:
in case of an off state, in the channel portion, a charge density of a region overlapping the second gate electrode is higher than a charge density of a region overlapping the first gate electrode; and
in the channel portion, the charge density of the region overlapping the first gate electrode is higher than a charge density of a region overlapping the third gate electrode.

19. The thin film transistor of claim 12,
wherein, in case of an on state, in the channel portion, a horizontal electric field intensity of a region overlapping the second gate electrode is smaller than a horizontal electric field intensity of a region overlapping the third gate electrode.

20. A display apparatus including the thin film transistor of claim 1.
